(19) United States
(12) Patent Application Publication
(10) Pub. No.: US 2026/0317904 A1
(43) Pub. Date: Oct. 15, 2026

(54) THIN FILMS CONTAINING SILICON, NITROGEN, AND CARBON

(71) Applicant: ASM IP Holding B.V., Almere (NL)

(72) Inventors: Dieter Pierreux, Pepingen (BE); Charles Dezelah, Helsinki (FI)

(21) Appl. No.: 19/639,415

(22) Filed: Apr. 6, 2026

Related U.S. Application Data
(60) Provisional application No. 63/786,006, filed on Apr. 9, 2025.

(51) Int. Cl. C23C 16/455; C01B 21/082; C23C 16/36; C23C 16/52

(52) U.S. Cl. CPC C23C 16/45553; C01B 21/0828; C23C 16/36; C23C 16/45544; C23C 16/52

(57) ABSTRACT

The present invention relates to methods and systems for depositing thin films containing silicon, nitrogen, and carbon, and to the thin films. The methods and systems make use of vapor-phase silicon precursor comprising a silicon compound, and a vapor-phase nitrogen precursor comprising an organic amine.

### CROSS-REFERENCE TO RELATED APPLICATIONS

This application claims priority to U.S. Provisional Patent Application Ser. No. 63/786,006, filed Mar. 9, 2025 and titled THIN FILMS CONTAINING SILICON, NITROGEN, AND CARBON, the disclosures of which is hereby incorporated by reference in its entirety.

### TECHNICAL FIELD OF THE INVENTION

The present invention relates to semiconductor thin film deposition, and more specifically to methods for depositing thin films containing silicon, nitrogen, and carbon.

### BACKGROUND OF THE INVENTION

Thin films containing silicon, nitrogen, and carbon, such as silicon nitride layers, are extensively utilized in semiconductor applications due to their excellent insulating properties, chemical stability, and compatibility with silicon-based technologies. These layers serve critical functions in microelectronic devices, including acting as diffusion barriers, dielectric materials, and protective coatings.

In the advancement of logic and memory integration, there is a significant interest in developing low thermal budget layers containing silicon, nitrogen, and carbon that exhibit high etch selectivity relative to materials like silicon oxide. High etch selectivity is advantageous for precise pattern transfer and device fabrication processes. Traditionally, achieving low wet etch rate ratios has involved depositing such thin films at elevated temperatures, which can lead to undesirable effects such as thermal stress or damage to temperature-sensitive components.

However, depositing layers containing silicon, nitrogen, and carbon at lower temperatures, particularly below 500° C. using deposition methods like chemical vapor deposition, in particular atomic layer deposition (ALD), often results in films with reduced etch selectivity. This limitation presents challenges in fabricating advanced semiconductor devices where maintaining film integrity and performance at lower processing temperatures is wanted.

There is thus still a need in the art for devices and methods that address at least some of the above problems.

### SUMMARY OF THE INVENTION

It is an objective of the present invention to provide substrate processing systems and methods for depositing thin layers containing silicon, nitrogen, and carbon, and to said thin films, that address at least some of the above addressed problems.

The above objective is accomplished by a method and apparatus according to the present invention.

In a first aspect, the present invention relates to a method for depositing a thin film comprising silicon, nitrogen, and carbon on a substrate. The method comprises providing the substrate in a reaction chamber. The method, then, comprises providing into the reaction chamber:
a vapor-phase silicon precursor comprising a silicon compound, wherein the silicon compound is selected from a group consisting of SiR¹R²R³R⁴ and R⁵R⁶R⁷Si—(XR⁸R⁹)ₘ—SiR¹⁰R¹¹R¹²,
   wherein m is an integer in the range from 0 to 4,
   wherein each X is independently selected from a group consisting of Si and C,
   wherein each R is independently selected from a group consisting of halogen, H, and optionally substituted C1 to C8 groups,
   wherein at least one R is halogen, and
   wherein each halogen, if present, is independently selected from a group consisting of F, Cl, Br, and I, and
a vapor-phase nitrogen precursor comprising an organic amine, thereby forming the thin film on a portion of a surface of the substrate.

In a second aspect, the present invention relates to a substrate processing system for depositing a thin film comprising silicon, nitrogen, and carbon on each of a plurality of substrates. The system comprises a reaction chamber configured to receive a substrate carrier supporting the plurality of substrates. The system further comprises a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen.

The system further comprises a second gas injector configured for providing a vapor-phase nitrogen precursor comprising an organic amine to the reaction chamber. The system further comprises a heater configured for heating and maintaining a process temperature in the reaction chamber. The system further comprises a controller configured to control the substrate processing system so as to form the thin film on each of the plurality of substrates.

In a third aspect, the present invention relates to a substrate processing system for depositing a thin film comprising a silicon, nitrogen, and carbon on a substrate. The system comprises a reaction chamber for receiving the substrate. The system further comprises a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen.

The system further comprises a second gas injector configured for providing a vapor-phase nitrogen precursor comprising an organic amine to the reaction chamber. The system further comprises a controller configured to control the substrate processing system so as to form said thin film on said substrate.

In a fourth aspect, the present invention relates to a thin film comprising silicon, nitrogen, and carbon. The film has a wet etch rate ratio of at most 0.5.

It is an advantage of embodiments of the present invention that doping the film with carbon may yield thin films having a good etch selectivity.

It is an advantage of embodiments of the present invention that the deposition process allows for advanced integration in logic and memory applications due to low thermal budget requirements.

It is an advantage of embodiments of the present invention that pure films, e.g., containing substantially only silicon, nitrogen and carbon, can be formed. It is an advantage of embodiments of the present invention that unwanted contaminants may be reduced by introducing the carbon component directly into at least the nitrogen precursors. It is an advantage of embodiments of the present invention that optimized electronic properties of the thin films can be achieved through controlled doping strategies. It is, indeed, an advantage of embodiments of the present invention that thin films may be obtained with specific properties, not obtained or not adequately obtained when contaminants are present. It is, therefore, an advantage of embodiments of the present invention that thin films may be deposited with precise control over composition and properties. It is an advantage of embodiments of the present invention that high-quality thin films can be formed.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a schematic view of a substrate processing system for depositing a thin film comprising silicon, nitrogen, and carbon on each of a plurality of substrates according to embodiments of the present invention.

FIG. 2 is a block diagram summarizing process steps that may be performed in a method for depositing a thin film comprising silicon, nitrogen, and carbon on a substrate in accordance with embodiments of the present invention.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

Although “comprising” should not be understood as being limited to “consists of”, the term “comprises” typically also encompasses, as a limiting case (e.g., in the limit of “no other elements or steps present”), the term “consists of”. As such, throughout the present description, each instance of the term “comprises” may independently be replaced by the term “consists of”.

As used herein, and unless otherwise specified, any parameters or properties mentioned throughout the description, such as: an electrical property; an electrical, ionic, thermal, or any other, conductivity; a phase or state change, such as a glass, melting or boiling point; a mechanical property, such as tensile strength, ductility or hardness; a density; a viscosity; a heat capacity; a solubility; or any other parameter or property, may be as determined under standard conditions, e.g., at 25° C. and/or 1 atm (i.e., 101325 Pa).

The following terms are provided solely to aid in the understanding of the invention.

Throughout the description, and unless otherwise stated, when mention is made of at-%, or atomic percentage, of an element of the thin film, the at-% may be as determined using X-ray photoelectron spectroscopy and may be measured as relative %, e.g., as part of the total amount of atoms in the thin film.

As used herein, and unless otherwise stated, the term “layer” and/or “(thin) film” can refer to any continuous or non-continuous material, such as material deposited by the methods disclosed herein. The terms “layer” and “(thin) film” may be used interchangeably. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous.

As used herein, and unless otherwise specified, the term “optionally substituted Cx to Cy group” typically refers to an organic group containing from x to y carbon atoms, which may be bonded to each other to form a linear, branched, or cyclic group, typically a hydrocarbon group, and which may optionally be substituted with, for example, halogen atoms, hydroxyl groups, amino groups, or other organic or inorganic substituents. The group may be saturated or unsaturated. Examples of an optionally substituted C1 group are —CH₃ and —CH₂Cl. Examples of an optionally substituted C2 group are —C₂H₅, —C₂H₃ and —C₂H₄Cl. Examples of an optionally substituted C3 group are —C₃H₇ (i.e., linear), —CH(CH₃)₂ (i.e., branched), and —C₃H₆Cl. Examples of an optionally substituted C6 group are —C₆H₁₃ (i.e., linear), -phenyl (i.e., cyclic, that is, aryl), and —C₅H₈(CH₃) (that is, methyl-substituted cyclopentyl).

As used herein, and unless otherwise specified, the term “optionally substituted x to y membered carbon-containing ring” typically refers to a cyclic ring structure comprising from x to y atoms, bonded to each so as to form the (x to y membered) cyclic ring. Amongst said atoms is at least one carbon atom. The ring may be saturated or unsaturated, and may optionally have substituents such as halogens, alkyl groups, or other functional groups.

In a first aspect, the present invention relates to a method for depositing a thin film comprising silicon, nitrogen, and carbon on a substrate. The method comprises providing the substrate in a reaction chamber. The method, then, comprises providing into the reaction chamber:
a vapor-phase silicon precursor comprising a silicon compound, wherein the silicon compound is selected from a group consisting of SiR¹R²R³R⁴ and R⁵R⁶R⁷Si—(XR⁸R⁹)ₘ—SiR¹⁰R¹¹R¹²,
   wherein m is an integer in the range from 0 to 4,
   wherein each X is independently selected from a group consisting of Si and C,
   wherein each R is independently selected from a group consisting of halogen, H, and optionally substituted C1 to C8 groups,
   wherein at least one R is halogen, and
   wherein each halogen, if present, is independently selected from a group consisting of F, Cl, Br, and I, and
a vapor-phase nitrogen precursor comprising an organic amine, thereby forming the thin film on a portion of a surface of the substrate.

The silicon compound is suitable for use as a precursor in vapor-phase deposition processes to deposit silicon-containing films.

In embodiments of the present invention, the halogen atom bonded to the silicon atom may facilitate bonding of the silicon to the surface on deposition by chemisorption of the silicon compound.

The optionally substituted C1 to C8 groups may independently be linear, branched, or may contain a ring structure, such as an aryl. In embodiments, each of the optionally substituted C1 to C8 groups may independently be selected from linear or branched C1 to C8 groups. In embodiments, each of the optionally substituted C1 to C8 groups of the silicon compound may independently be selected from optionally substituted C1 to C6 groups, preferably from optionally substituted C1 to C4 groups. In embodiments, the optionally substituted C1 to C8 groups may independently be saturated or unsaturated. In some embodiments, each of the optionally substituted C1 to C8 groups is saturated. In embodiments, each of the optionally substituted C1 to C8 groups may be selected from optionally substituted C1 to C6 alkyls, preferably from optionally substituted C1 to C4 alkyls. In embodiments, each of the optionally substituted C1 to C8 groups may be selected from C1 to C6 haloalkyls and C1 to C6 alkyls, preferably from C1 to C4 haloalkyls and C1 to C4 alkyls.

In embodiments, each of the optionally substituted C1 to C8 groups may be independently selected from:
optionally substituted linear or branched C1 to C6 alkyls, and
optionally substituted aryls. Said optionally substituted C1 to C8 groups being optionally substituted aryls are typically C1 to C8 groups containing said aryl. The aryl may, for example, by a substituted phenyl group, substituted with up to two methyl groups or with an ethyl group.

In embodiments, each optionally substituted C1 to C8 group may independently be selected from an optionally substituted alkyl group, an optionally substituted alkenyl group, an optionally substituted alkynyl group, or an optionally substituted phenyl group.

In embodiments, each R is independently selected from a group consisting of halogen, H, and optionally substituted C1 to C6 groups. In embodiments, each R is independently selected from a group consisting of halogen, H, optionally substituted C1 to C6 alkyls, and optionally substituted aryls. In embodiments, if said R is halogen, each R may be independently selected from a group consisting of F, Cl, Br, and I. In embodiments, if said R is halogen, R may be Cl.

In embodiments, each optional substituent is, if present, independently selected from a group consisting of F, Cl, Br, and I. Preferably, each optional substituent, if present, is Cl. Halogens are typically not introduced into the thin film to be formed, so that, in these embodiments, the thin film may have a high purity.

In embodiments, at least one of the optional substituents may contain N, e.g., may be NH₂. As the thin film to be formed contains N, the optional substituent containing N may contribute to the N content, or to the homogeneity of the N content, of the thin film. In embodiments, at least one of the optional substituents may contain O, e.g., may be OH. These embodiments may be particularly advantageous if the thin film to be formed further contains O. In embodiments, each of the optional substituents is independently selected from a group consisting of substituents containing N, substituents containing O, and halogens selected from F, Cl, Br, and I. In embodiments, each of the optional substituents, different from substituents containing N and/or O, is Cl.

In some embodiments, the silicon compound contains no said optional substituents.

In embodiments, the silicon compound may have the chemical formula SiR¹R²R³R⁴, wherein each R is independently selected from a group consisting of halogen, H, and optionally substituted C1 to C8 groups, wherein at least one R is halogen.

In embodiments, at least one selected from R¹, R², R³ and R⁴ is a halogen, e.g., Cl. In embodiments, at least two selected from R¹, R², R³ and R⁴ are halogen atoms. In embodiments, at least three selected from R¹, R², R³ and R⁴ are halogen atoms. In embodiments, each of R¹, R², R³ and R⁴ may be halogen atoms, e.g., Cl. In embodiments, the silicon compound may be SiCl₄. In these embodiments, the silicon compound typically only provides silicon to the thin film.

In embodiments, at least R¹ is a halogen. In these embodiments, at least one selected from R², R³ and R⁴ may be independently selected from said optionally substituted C1 to C8 groups, preferably from optionally substituted C1 to C4 groups, more preferably from optionally substituted C1 to C4 alkyls. In these embodiments, at least two selected from R², R³ and R⁴ may be independently selected from optionally substituted C1 to C8 groups, preferably from optionally substituted C1 to C4 groups, more preferably from optionally substituted C1 to C4 alkyls. In these embodiments, each of R², R³ and R⁴ may be independently selected from said optionally substituted C1 to C8 groups, preferably from optionally substituted C1 to C4 groups, more preferably from optionally substituted C1 to C4 alkyls. These silicon compounds provide a source of both silicon and carbon, and the presence of the halogen atoms make them particularly suitable for self-limiting reactions in atomic layer deposition.

In embodiments, the silicon compound may be a chloro-organosilane. In embodiments, the silicon compound may have the chemical formula SiCl₂R³R⁴ (corresponding to R¹=chlorine and R²=chlorine). In these embodiments, R³ may be selected from chlorine (i.e., Cl) and said optionally substituted C1 to C8 groups, preferably from chlorine and optionally substituted C1 to C4 groups, more preferably from chlorine and optionally substituted C1 to C4 alkyls, e.g., from chlorine and C1 to C4 alkyls and C1 to C4 chloroalkyls. In these embodiments, R⁴ may be selected from said optionally substituted C1 to C8 groups, preferably from optionally substituted C1 to C4 groups, more preferably from optionally substituted C1 to C4 alkyls, e.g., from C1 to C4 alkyls and C1 to C4 chloroalkyls.

In embodiments, the silicon compound may have the chemical formula R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H,
and optionally substituted C1 to C8 groups,
wherein at least one R is halogen.

In embodiments, m may be 0. In these embodiments, the silicon compound is typically called a “disilane”. In different embodiments, m may be an integer in the range from 1 to 4.

In embodiments, each R may be a halogen, e.g., Cl.

In different embodiments, at least one of the R groups of the R⁵R⁶R⁷Si—(XR⁸R⁹)ₘ—SiR¹⁰R¹¹R¹² may be selected from the optionally substituted C1 to C8 groups. These compounds provide a source of both silicon and carbon, and the presence of the halogen atoms make them particularly suitable for self-limiting reactions in atomic layer deposition. In embodiments, if X is C, said X being C may also be a source of carbon for the thin film.

In embodiments, the X atoms form a linear chain with the Si atoms at the respective ends of the linear chain, wherein R⁸ and R⁹ are side groups or substituents on the X atoms. In embodiments, each X, if present, may be Si. In embodiments, each X, if present, may be C. In some embodiments, if m is an integer in a range from 2 to 4, the different X atoms, if present, may form a combination of Si and C atoms.

In embodiments, e.g., when m is an integer in a range from 2 to 4, the different R⁸ groups may be the same or may be different. In embodiments, e.g., if m is an integer in a range from 2 to 4, the different R⁹ groups may be the same or may be different.

In embodiments, each of R⁵, R⁶, R⁷, R¹⁰, R¹¹, and R¹² may be independently selected from a group consisting of halogen, H, and optionally substituted C1 to C8 groups. In embodiments, each of R⁵, R⁶, R⁷, R¹⁰, R¹¹, and R¹² may be independently selected from a group consisting of halogen, H, and optionally substituted C1 to C6 groups. In embodiments, each of R⁵, R⁶, R⁷, R¹⁰, R¹¹, and R¹² may be independently selected from a group consisting of halogen, H, and optionally substituted C1 to C6 alkyls. In embodiments, at least one selected from R⁵, R⁶, R⁷, R¹⁰, R¹¹, and R¹² is halogen, e.g., Cl. In embodiments, at least one selected from R⁵, R⁶ and R⁷, and at least one selected from R¹⁰, R¹¹, and R¹², is halogen, e.g., Cl. In embodiments, at least one selected from R⁵, R⁶, R⁷, R¹⁰, R¹¹, and R¹² is an optionally substituted C1 to C8 group. In embodiments, each of at least one selected from R⁵, R⁶, and R⁷, and at least one selected from R¹⁰, R¹¹, and R¹², is independently selected from optionally substituted C1 to C8 groups, preferably from optionally substituted C1 to C4 groups, more preferably from optionally substituted C1 to C4 alkyls, even more preferably from C1 to C4 alkyls or from C1 to C4 haloalkyls.

In embodiments, each R⁸ and each R⁹ may be independently selected from a group consisting of halogen, H, and optionally substituted C1 to C8 groups. In embodiments, each R⁸ and each R⁹ may be independently selected from a group consisting of halogen, H, and optionally substituted C1 to C4 groups. In embodiments, each R⁸ and each R⁹ may be independently selected from a group consisting of halogen, H, and optionally substituted C1 to C4 alkyls. In embodiments, each R⁸ and each R⁹ may be independently selected from a group consisting of halogen, H, and optionally substituted C1 to C2 alkyls. In embodiments, each R⁸ and each R⁹ may be independently selected from a group consisting of halogen and H.

In embodiments, each R⁸ and each R⁹ may be H. In embodiments, for each X that is Si, at least one selected from R⁸ and R⁹ bonded to said Si may be halogen, e.g., Cl.

In embodiments, the silicon compound may be a chloro-organodisilane. In embodiments, the silicon compound may have the chemical formula ClR⁶R⁷Si—SiClR¹¹R¹² (corresponding to m=0, R⁵=chlorine, and R¹⁰=chlorine). In these embodiments, each of R⁶ and R¹¹ may be independently selected from chlorine (i.e., Cl) and said optionally substituted C1 to C8 groups, preferably from chlorine and optionally substituted C1 to C4 groups, more preferably from chlorine and optionally substituted C1 to C4 alkyls, e.g., from chlorine and C1 to C4 alkyls and C1 to C4 chloroalkyls. In these embodiments, each of R⁷ and R¹² may be independently selected from said optionally substituted C1 to C8 groups, preferably from optionally substituted C1 to C4 groups, more preferably from optionally substituted C1 to C4 alkyls, e.g., from C1 to C4 alkyls and from C1 to C4 chloroalkyls.

In embodiments, the silicon compound may be a chloro-organodisilyl ClR⁶R⁷Si—(XR⁸R⁹)m—SiClR¹¹R¹², wherein m is an integer in the range from 1 to 4 (corresponding to R⁵=chlorine and R¹⁰=chlorine). In these embodiments, each of R⁶ and R¹¹ may be independently selected from chlorine (i.e., Cl) and said optionally substituted C1 to C8 groups, preferably from chlorine and optionally substituted C1 to C4 groups, more preferably from chlorine and optionally substituted C1 to C4 alkyls, e.g., from chlorine and C1 to C4 alkyls and C1 to C4 chloroalkyls. In these embodiments, each of R⁷ and R¹² may be independently selected from said optionally substituted C1 to C8 groups, preferably from optionally substituted C1 to C4 groups, more preferably from optionally substituted C1 to C4 alkyls, e.g., from C1 to C4 alkyls and from C1 to C4 chloroalkyls. In these embodiments, each of R⁸ and R⁹ may be independently selected from H, chlorine, said optionally substituted C1 to C8 groups, preferably from H, chlorine, and optionally substituted C1 to C4 groups, more preferably from H, chlorine, and optionally substituted C1 to C4 alkyls, e.g., from C1 to C4 alkyls and from C1 to C4 chloroalkyls. In these embodiments, preferably, each of R⁸ and R⁹ may be independently selected from H and chlorine, e.g., may be H.

In some embodiments, the silicon compound is a silicon halide, e.g., a silicon chloride. In embodiments, the silicon halide may consist of from 1 to 6 silicon atoms, preferably from 1 to 3 silicon atoms-that may be bonded to each other to form a linear or branched group of silicon atoms, typically a linear group of silicon atoms- and halogen atoms, e.g., Cl, bonded to the silicon atoms. In embodiments, the silicon compound may be SiCl₄, octachlorotrisilane or hexachlorodisilane. In embodiments, the silicon compound may be octachlorotrisilane or hexachlorodisilane. These embodiments appear to provide particularly good and pure films.

In embodiments, the silicon compound may comprise carbon. In these embodiments, the silicon compound may provide silicon and carbon to the thin film.

In embodiments, the silicon compound may comprise, or may be, a chloroalkylsilane—wherein the alkyl may or may not be optionally substituted—such as trichloromethylsilane (SiCl₃Me), vinyltrichlorosilane (SiCl₃(C₂H₃)), or trichloro(chloromethyl)silane (SiCl₃(CH₂Cl)). In embodiments, the silicon compound may comprise, or may be, a chloroarylsilane—wherein the aryl may or may not be optionally substituted—such as phenyltrichlorosilane (SiCl₃Ph). In embodiments, the silicon compound may comprise, or may be, a chloroalkyldisilane (typically containing two silicon atoms bonded to each other, and at least one Cl atom and at least one alkyl group bonded to the silicon atoms, e.g., to each of the two silicon atoms), such as 1,2-dichloro-1,1,2,2-tetramethyldisilane (ClMe₂Si—SiClMe₂) or 1,1,2,2-tetrachloro-1,2-dimethyldisilane (Cl₂MeSi—SiCl₂Me). In embodiments, the silicon compound may comprise, or may be, a chlorodisilylalkane (typically containing two silane groups each bonded to an alkane chain, and a Cl atom bonded to one or both of the silicon atoms of the two silane groups) such as 1,1′-methylenebis[1,1,1,-trichlorosilane] (CH₂(SiCl₃)₂).

In embodiments, the organic amine may be a nitrogen-containing compound that can serve as a vapor-phase nitrogen precursor in deposition processes to deposit nitrogen-containing films. The organic amine is typically an amine containing an organic group, and thus typically contains carbon. Said carbon is typically deposited into the thin film together with the nitrogen of the organic amine.

In embodiments, the organic amine contains a nitrogen atom bonded to an organic group. In embodiments, the organic group may be an optionally substituted C1 to C8 group, preferably an optionally substituted C1 to C6 group, more preferably an optionally substituted C1 to C4 group. In embodiments, the organic group may contain a carbon containing, four to ten membered, preferably five to eight membered, ring, said ring containing said nitrogen atom. Said ring is typically a heterocycle containing said nitrogen atom as heteroatom, and may for the rest be formed of carbon atoms.

In embodiments, the organic amine may further contain, bonded to the nitrogen atom, further organic groups, a further nitrogen atom, an oxygen atom or a halogen, such as Cl.

In embodiments, the organic amine has the chemical formula NR¹³R¹⁴R¹⁵. In embodiments, R¹³ is an optionally substituted C1 to C8, preferably an optionally substituted C1 to C6, more preferably an optionally substituted C1 to C4, group. In embodiments, each of R¹⁴ and R¹⁵ is independently selected from H and optionally substituted C1 to C8, preferably optionally substituted C1 to C6, more preferably optionally substituted C1 to C4, groups.

In embodiments, R¹³ and R¹⁴ together with N form an optionally substituted four to ten, preferably five to nine, more preferably five to eight, membered carbon-containing ring, and wherein:
R¹⁴ and R¹⁵ together with N form an optionally substituted four to ten, preferably five to nine, more preferably five to eight, membered carbon-containing ring, or
R¹⁵ is selected from H and optionally substituted C1 to C8, preferably optionally substituted C1 to C6, more preferably optionally substituted C1 to C4, groups.

In embodiments, each of R¹³, R¹⁴ and R¹⁵ is independently selected from optionally substituted C1 to C8 groups, preferably from optionally substituted C1 to C6 groups, more preferably from optionally substituted C1 to C4 groups, even more preferably from optionally substituted C1 to C4 alkyls.

In embodiments, the organic amine has the chemical formula NR¹³R¹⁴R¹⁵, wherein:
R¹³ is an optionally substituted C1 to C4 group, and wherein each of R¹⁴ and R¹⁵ is independently selected from H and optionally substituted C1 to C4 groups, or
R¹³ and R¹⁴ together with N form an optionally substituted five to eight membered carbon-containing ring, and wherein:
   R¹⁴ and R¹⁵ together with N form an optionally substituted five to eight membered carbon-containing ring, or
   R¹⁵ is selected from H and optionally substituted C1 to C4 groups.

In any of the above embodiments, the carbon-containing ring may—apart from said N contained in the ring—be formed of carbon atoms (that may be bonded to hydrogen atoms and/or optional substituents). The carbon-containing ring may be substituted, e.g., with halogen atoms such as chlorine, or may be unsubstituted. The carbon-containing ring may be saturated or unsaturated.

In embodiments, R¹³ may be an optionally substituted C1 to C4 group, preferably a C1 to C4 alkyl, and each of R¹⁴ and R¹⁵ may be independently selected from a group consisting of H and optionally substituted C1 to C4 groups, preferably from H and C1 to C4 alkyls. In embodiments, R¹³ may be an optionally substituted C1 to C4 group, preferably a C1 to C4 alkyl, and each of R¹⁴ and R¹⁵ may be H. In preferred embodiments, the organic amine may be ethylamine (H₂NC₂H₅) or methylamine (H₂NCH₃), preferably methylamine.

In embodiments, the organic amine may have the chemical formula R¹⁶R¹⁷N—(CR¹⁸R¹⁹)_{y}—NR²⁰R²¹ with y an integer in the range from 1 to 4. Herein, the y C atoms typically form a chain with the N atoms at the ends, and with each of said y C atoms bonded to a R¹⁸ and a R¹⁹. In embodiments, e.g., if y is at least 2, each R¹⁸ may be the same or different. In embodiments, e.g., inf y is at least 2, each R¹⁹ may be the same or different. In these embodiments, each of R¹⁶ and R¹⁷ may be independently selected from H and optionally substituted C1 to C8 groups, or R¹⁶ and R¹⁷ together with the N to which they are bonded form an optionally substituted four to ten membered ring, preferably an optionally substituted five to eight membered ring. In these embodiments, each of R²⁰ and R²¹ may be independently selected from H and optionally substituted C1 to C8 groups, or R²⁰ and R²¹ together with the N to which they are bonded form an optionally substituted four to ten membered ring, preferably an optionally substituted five to eight membered ring. In these embodiments, each R¹⁸ and R¹⁹ may be independently selected from H and optionally substituted C1 to C8 groups.

In embodiments, each of R¹⁶, R¹⁷, R²⁰, and R²¹ may be independently selected from H and optionally substituted C1 to C8 groups. In embodiments, each of R¹⁶, R¹⁷, R²⁰, and R²¹ may be independently selected from H and optionally substituted C1 to C6 groups. In embodiments, each of R¹⁶, R¹⁷, R²⁰, and R²¹ may be independently selected from H and optionally substituted C1 to C4 groups. In embodiments, each of R¹⁶, R¹⁷, R²⁰, and R²¹ may be independently selected from H and optionally substituted C1 to C4 alkyls.

In embodiments, each R¹⁸ and R¹⁹ may be independently selected from H and optionally substituted C1 to C8 groups. In embodiments, each R¹⁸ and R¹⁹ may be independently selected from H and optionally substituted C1 to C6 groups. In embodiments, each R¹⁸ and R¹⁹ may be independently selected from H and optionally substituted C1 to C4 groups. In embodiments, each R¹⁸ and R¹⁹ may be independently selected from H and optionally substituted C1 to C4 alkyls. In embodiments, each R¹⁸ and R¹⁹ may be H.

In embodiments, each of R¹⁶, R¹⁷, R²⁰, and R²¹ is H. In embodiments, the organic amine may have the chemical formula H₂N—(CR¹⁸R¹⁹)_{y}—NH₂, e.g., H₂N—(CH₂)_{y}—NH₂, with y an integer in the range from 1 to 4, preferably 2.

In some embodiments, the organic amine may have the chemical formula R¹⁶R¹⁷N—NR²⁰R²¹ (which may correspond to the chemical formula R¹⁶R¹⁷N—(CR¹⁸R¹⁹)_{y}—NR²⁰R²¹ with y equal to 0), in which case the organic amine may alternatively be called a substituted hydrazine or a hydrazine derivative. In these embodiments, at least one selected from R¹⁶, R¹⁷, R²⁰, and R²¹ contains carbon. In these embodiments, at least one selected from R¹⁶, R¹⁷, R²⁰, and R²¹ may be an optionally substituted C1 to C8 group, preferably an optionally substituted C1 to C4 group, more preferably an optionally substituted C1 to C4 alkyl. In these embodiments, R¹⁶ and R¹⁷ together with the N to which they are bonded may form an optionally substituted four to ten membered ring, preferably an optionally substituted five to eight membered ring. In these embodiments, R²⁰ and R²¹ together with the N to which they are bonded may form an optionally substituted four to ten membered ring, preferably an optionally substituted five to eight membered ring. In some embodiments, the hydrazine derivative may be selected from a group consisting of: tert-butylhydrazine (C₄H₉N₂H₃), methylhydrazine (CH₃NHNH₂), 1,1-dimethylhydrazine ((CH₃)₂NNH₂), 1,2-dimethylhydrazine (CH₃)NHNH(CH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, and azo-tert-butane.

In embodiments of the organic amine, at least one of the optional substituents of said organic amine may contain N, e.g., may be NH₂. As the thin film to be formed contains N, the optional substituent containing N may contribute to the N content, or to the homogeneity of the N content, of the thin film. In embodiments of the organic amine, at least one of the optional substituents of said organic amine may contain O, e.g., may be OH. These embodiments may be particularly advantageous if the thin film to be formed further contains O. In embodiments, each of the optional substituents of said organic amine is independently selected from a group consisting of substituents containing N, substituents containing O, and halogens selected from F, Cl, Br, and I. In embodiments of the organic amine, each of the optional substituents, if present, of said organic amine may be independently selected from a group consisting of F, Cl, Br, and I. In embodiments of the organic amine, each of the optional substituents is Cl.

In embodiments, the organic amine does not contain said optional substituents.

In embodiments, the step of providing said silicon precursor and said nitrogen precursor may be performed at a temperature of at most 650° C., preferably at most 600° C., more preferably at most 500° C., even preferably at most 450° C., yet more preferably at most 400° C.. Lower deposition temperatures may be desirable for thermal budget reasons. Furthermore, when lower temperatures are used, in particular when deposited during back-end-of-line processing, damage to structures or devices already present in the substrate may be limited. However, in particular in vertical furnace reactors such as substrate processing systems in accordance with embodiments of the second aspect of the present invention, higher temperatures typically result in higher quality layers. It is an advantage of embodiments of the present invention that the thin layers of the present invention can be deposited at low temperatures, even below 500° C. or below 400° C., while maintaining high etch selectivity. It is an advantage of embodiments of the present invention that the deposition process allows for advanced integration in logic and memory applications due to low thermal budget requirements.

In some embodiments, the nitrogen precursor may further contain a carbon-less nitrogen source. In other words, the nitrogen precursor may contain the organic amine, which contains carbon, and in addition a carbon-less nitrogen source, i.e., a nitrogen source not containing carbon.

In embodiments, the carbon-less nitrogen source has a chemical formula that includes nitrogen and hydrogen. In embodiments, the carbon-less nitrogen source does not include diatomic nitrogen. In embodiments, the carbon-less nitrogen source may be selected from one or more of ammonia (NH₃), hydrazine (N₂H₄), and other compounds comprising or consisting of nitrogen and hydrogen. For example, a mixture of nitrogen gas and hydrogen gas may be used. In embodiments, the carbon-less nitrogen source does not include diatomic nitrogen, i.e., the carbon-less nitrogen source is a non-diatomic precursor.

In some embodiments, the carbon-less nitrogen source is selected from a group consisting of molecular nitrogen (N₂), ammonia (NH₃), hydrazine (NH₂NH₂). In some embodiments, the carbon-less nitrogen source does not contain silicon, i.e., the carbon-less nitrogen source may be silicon-free.

As atoms deposited by the nitrogen precursor and the silicon precursor may be limited to nitrogen, silicon and carbon, doping of the deposited film may be controlled. This may be in particular in contrast with methods in which the carbon is, instead, provided by other precursors or molecules than the silicon and nitrogen precursor, as in the latter case contaminations may be introduced by said other precursors or molecules. In addition, as the carbon is already incorporated in the organic amine and optionally in the silicon compound, the present method allows for high carbon doping levels, such as up to 50 wt-% carbon. This may be advantageous as etch selectivity may increase with carbon content.

In embodiments, the deposition method may be a chemical vapor deposition process. In embodiments, the deposition method may be a cyclic chemical vapor deposition process, such as an atomic layer deposition process.

In embodiments, the chemical vapor deposition process may be characterized by vapor deposition which is not self-limiting. The nitrogen precursor and the silicon precursor, and optionally a co-reactant such as an oxygen precursor, may be provided simultaneously to the reaction chamber or substrate, or in partially or completely separated pulses. In embodiments, the chemical vapor deposition process may involve gas phase reactions between the nitrogen precursor and the silicon precursor, and optionally said optional co-reactant. In some embodiments, the nitrogen precursor and the silicon precursor, and optionally said optional co-reactant, are provided simultaneously until a layer having a desired thickness is deposited.

In some embodiments, cyclic chemical vapor deposition processes can be used with multiple cycles to deposit a thin film having a desired thickness. In cyclic chemical vapor deposition processes such as atomic layer deposition, the precursors and/or any co-reactants may be provided to the reaction chamber in pulses that do not overlap, or that partially or completely overlap.

In preferred embodiments, the present invention relates to cyclical deposition processes, such as atomic layer deposition. In embodiments, the method may be an atomic layer deposition process comprising pulsing, cyclically, into said reaction chamber, said silicon precursor, and then said nitrogen precursor. Atomic layer deposition allows for precise control over the film thickness and composition.

In cyclic deposition processes, during each cycle, the silicon precursor is introduced into the reaction chamber and the silicon compound may be chemisorbed to the substrate surface (wherein the substrate surface may be the bare substrate, or may include a previously deposited material from a previous deposition cycle, or another material). In embodiments, one or more halogen atoms bonded to the silicon atom may react to leave the silicon compound and the silicon atom may bind to the substrate surface. Thereby, a silicon-containing layer may be formed. In some embodiments, the silicon compound on the substrate surface does not readily react with the silicon compound itself, so that the deposition of the silicon compound may be partially or fully self-limiting. Thereafter, the organic amine may be introduced into the reaction chamber for depositing nitrogen thereby forming the thin film containing the silicon, nitrogen and carbon. In particular, the organic amine may be capable of further reaction with the chemisorbed silicon compound, forming a silicon-nitrogen bond. Thereby, the organic amine may be chemisorbed to the substrate surface, e.g., forming a bond with the chemisorbed silicon compound.

As the organic amine, and optionally the silicon compound, further comprises carbon, said formed thin film or layer may contain carbon as well, that is, may be carbon-doped by the carbon of the organic amine and optionally of the silicon compound. In embodiments, the organic amine does not readily react with the organic amine itself, so that the reaction between the organic amine and the chemisorbed silicon compound may be self-limiting as well. Thereby, the silicon-containing thin film or layer may be transformed into a silicon, nitrogen and carbon containing thin film or layer.

Thereafter, cyclically:
the silicon precursor may be introduced again into the reaction chamber so that
the silicon compound reacts with the layer for depositing silicon, and optionally carbon, on the layer, and
the nitrogen precursor may be provided again so that the organic amine reacts with the layer for depositing nitrogen and carbon on the layer.

Purging steps may be utilized to remove any excess precursor from the process chamber and/or remove any excess co-reactant and/or reaction byproducts from the reaction chamber. In embodiments, the cyclic deposition process comprises purging the reaction chamber after providing the silicon precursor, and before providing the nitrogen precursor, into the reaction chamber. In embodiments, the cyclic deposition process comprises purging the reaction chamber after providing the nitrogen precursor, and before providing the silicon precursor, into the reaction chamber.

In embodiments, the method comprises cyclically performing:
optionally purging the reaction chamber, then
providing, into the reaction chamber, said vapor-phase silicon precursor, then
optionally purging the reaction chamber, and then
providing, into the reaction chamber, said vapor-phase nitrogen precursor.

In embodiments, the method further comprises providing a vapor-phase co-reactant in the reaction chamber. The co-reactant may be provided simultaneously with the vapor-phase silicon precursor and/or with the vapor-phase nitrogen precursor. In preferred embodiments, the method comprises cyclically performing:
a) optionally purging the reaction chamber, then
   providing, into the reaction chamber, said vapor-phase silicon precursor,
b) optionally purging the reaction chamber, then
   providing, into the reaction chamber, said vapor-phase nitrogen precursor,
c) optionally purging the reaction chamber, and then
   providing, into the reaction chamber, said vapor-phase co-reactant.

The invention is not limited to a particular order of steps a, b and c within a single cycle. For example, the order within a cycle may be first a, then b, then c. For example, the order within a cycle may be first c, then b, then a. For example, the order within a cycle may be first b, then a, then c. The method may comprise cycles in which one or two of the steps a, b, and c are not performed, and other cycles in which any of the steps a, b, and c are performed multiple times.

In embodiments, at least some cycles may contain additional steps, in which additional precursors or compounds may be provided, not mentioned above. In embodiments, in some cycles, the nitrogen precursor may contain the organic amine, whereas in other cycles, the nitrogen precursor does not contain the organic amine. In embodiments, during some cycles, the nitrogen precursor may contain the organic amine and the silicon precursor may contain carbon as well, wherein in other cycles, neither contains carbon. The concentration of dopants in the thin film may be tuned by tuning the amount or fraction of cycles in which the organic amine, and the silicon compound containing carbon, is provided, so that these embodiments may be used to accurately tune the carbon concentration in the thin film. For example, in a cyclical deposition method in accordance with embodiments of the present invention, some cycles may comprise providing SiMeCl₃ as the silicon precursor and NH₂Me as the nitrogen precursor, and other cycles within the same method may comprise providing Si₂Cl₆ as the silicon precursor and NH₃ as the nitrogen precursor.

In embodiments, the co-reactant may be an oxygen precursor. The oxygen precursor may provide oxygen for forming the thin film further containing, e.g., doped by, oxygen. The oxygen precursor may be a gas or a material that can become gaseous and that can be represented by a chemical formula that includes oxygen. In embodiments, the method may comprise a step of providing an oxygen precursor into the reaction chamber, wherein the formed thin film is further doped with oxygen. Oxygen doping can further tune the film properties. The oxygen doping may result in a low k material, so that the formed oxygen- and carbon-containing thin film may be used as dielectric material for filling gaps, e.g., between metal interconnects. The oxygen doping may result in a material having a low gate leakage current density. Furthermore, the thus formed film may have a high resistance against hydrofluoric acid (HF). For example, the thus formed film may have a high resistance to hydrofluoric acid (HF) etching after it has undergone a plasma ashing process, so that the thus formed film may be used as masking layer. It is an advantage of embodiments of the present invention that optimized electronic properties of thin films can be achieved through controlled doping strategies. It is an advantage of embodiments of the present invention that the thin films of the present invention may be further doped with elements like oxygen to tailor film properties.

In some embodiments, the oxygen precursor is selected from a group that consists of water, molecular oxygen, hydrogen peroxide, nitrogen oxide such as N₂O, ozone and reactive oxygen species including ¹O₂ and O_{2·}⁻ or OH· radicals. In some embodiments, the oxygen precursor comprises hydrogen and oxygen. In some embodiments, the oxygen precursor does not contain carbon, i.e., is carbon-free. In some embodiments, the oxygen precursor does not contain silicon, i.e., is silicon-free. In some embodiments, the oxygen precursor comprises water. In some embodiments, the oxygen precursor is water. In some embodiments, the oxygen precursor is molecular oxygen. In some embodiments, the oxygen precursor comprises hydrogen peroxide. In some embodiments, the oxygen precursor is hydrogen peroxide. In some embodiments, the oxygen precursor is ozone. Depending on the selected oxygen precursor, the oxygen precursor may be liquid or gaseous in the precursor vessel. However, the invention is not limited thereto, and instead, solid precursors may be used.

In embodiments, the co-reactant may comprise boron. In these embodiments, the material that is formed on the portion of the surface may be a boride of the metal. In these embodiments, the co-reactant may comprise BCl₃.

In some embodiments, the co-reactant may be a hydrocarbon. The hydrocarbon may be aliphatic or aromatic. The hydrocarbon may be saturated or unsaturated, linear or branched, cyclic or acyclic. The hydrocarbon may comprise, for example, an alkyl halide, an alkene, an alkyne, or metal alkyl.

In some embodiments, the process comprises one or more acyclic (i.e., continuous) phases. In some embodiments, the deposition process comprises the continuous flow of the nitrogen precursor and/or the silicon precursor, and optionally the optional co-reactant. In such an embodiment, the process may comprise a continuous flow of one or both precursors.

In some embodiments, at least one of the nitrogen precursor and the silicon precursor and the optional co-reactant, is provided into the reaction chamber in pulses. In some embodiments, the nitrogen precursor is supplied in pulses, the silicon precursor is supplied in pulses, and the optional co-reactant is supplied in pulses, and the reaction chamber is purged between consecutive pulses. A duration of providing each of the precursors and the optional co-reactant into the reaction chamber (i.e., a pulse time for the nitrogen precursor, a pulse time for the silicon precursor, and a pulse time for the optional co-reactant, respectively) may each independently be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The pulse time for the nitrogen precursor, the pulse time for the silicon precursor, and the pulse time for the optional co-reactant, may each independently be, for example, 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, the pulse time for each precursor may be at least 5 seconds, or at least 10 seconds. In some embodiments, the pulse time for each precursor may be at most 5 seconds, or at most 10 seconds or at most 20 seconds, or at most 30 seconds. In some embodiments, the pulse time for the co-reactant may be at least 5 seconds, or at least 10 seconds, or at least 20 seconds. In some embodiments, the pulse time for the co-reactant may be at most 5 seconds, or at most 10 seconds or at most 20 seconds, or at most 30 seconds.

The concentration of the carbon in the thin film, and—if the optional co-reactant is an oxygen precursor—of the optional oxygen in the thin film, may be tuned by tuning the relative time of pulsing, or by tuning the relative number of pulses. For example, in part of the cycles of the cyclical deposition process, one or more of the precursors and the optional co-reactant may be omitted, thereby reducing the relative contribution of the omitted compound. The concentration of the carbon dopant may alternatively be tuned by tuning the number of carbon atoms provided in the organic amine and optionally in the silicon compound.

In some embodiments, providing the silicon precursor and/or providing the nitrogen precursor, and optionally providing the optional co-reactant, into the reaction chamber may comprise pulsing the silicon precursor and/or pulsing the nitrogen precursor, and optionally pulsing the optional co-reactant, into the reaction chamber over the substrate. In some embodiments, the silicon precursor may be pulsed more than one time, for example two, three or four times, before the nitrogen precursor and/or the optional co-reactant is pulsed to the reaction chamber. In some embodiments, the nitrogen precursor may be pulsed more than one time, for example two, three or four times, before the silicon precursor and/or the optional co-reactant is pulsed to the reaction chamber. Similarly, there may be more than one pulse, such as two, three, or four pulses, of the optional co-reactant before the nitrogen and/or silicon precursor is pulsed (i.e., provided) into the reaction chamber.

In embodiments, purging comprises removing any precursor and/or co-reactants, and/or vapor phase byproducts from the reaction chamber. Purging may comprise evacuating the reaction chamber with a vacuum pump and/or by replacing the gas inside a reaction chamber with an inert or substantially inert gas such as argon or nitrogen. Purging may limit or prevent interactions between, for example, the precursors, and between any precursor and the optional co-reactant, in the vapor phase. Purging may be effected either in time or in space, or both. In embodiments, a purge step may comprise providing a purge gas to the reaction chamber while simultaneously pumping gas from the reaction chamber, wherein the substrate on which the layer is deposited does not move. Said purging step may be performed for from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s, but other purge times can be utilized if necessary. When purging is effected in space, a purge step may comprise: moving the substrate from a first location to which the silicon precursor is continuously supplied, to a second location to which the nitrogen precursor is continuously supplied, through a purge gas curtain or another means of separating the first location from the second location.

The substrate being provided in the reaction chamber typically means that the substrate is in a space where deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of the vapor deposition method can be performed within a single reaction chamber, or they can be performed in multiple reaction chambers, such as reaction chambers of a cluster tool, or deposition stations of a multi-station processing chamber. The reaction chamber may be part of, or may be, a vertical furnace process chamber.

In embodiments, the reaction chamber is a semiconductor processing apparatus reaction chamber. In embodiments, the reaction chamber may be a flow-type reactor, such as a cross-flow reactor. In embodiments, the reaction chamber may be a showerhead reactor. In embodiments, the reaction chamber may be a space-divided reactor. In embodiments, the reaction chamber may be single wafer atomic layer deposition reactor. In embodiments, the reaction chamber may be a high-volume manufacturing single wafer atomic layer deposition reactor. In some embodiments, the reaction chamber may be a batch reactor for processing multiple substrates simultaneously.

The reaction chamber may form part of a vapor deposition system. The reaction chamber may form part of a chemical vapor deposition system. In embodiments, said chemical vapor deposition is atomic layer deposition. The reaction chamber can form part of an atomic layer deposition system. In embodiments, the system or the reaction chamber may be provided with a heater to activate reactions by elevating the temperature of one or more of the substrate and/or precursors and/or co-reactants.

The substrate may be a semiconductor wafer, such as a silicon wafer, a gallium arsenide wafer, a silicon carbide wafer, a germanium wafer, or an indium phosphide wafer, although the invention is not limited thereto. In embodiments, the portion of the surface of the substrate is reactive towards the silicon compound and/or the organic amine. In embodiments, the portion of the surface of the substrate may be functionalized for facilitating chemical adsorption (or chemisorption) of the silicon compound and/or the organic amine. In embodiments, the portion of the surface may be functionalized with a functional group selected from a group consisting of: hydroxyl groups, amino groups, carboxyl groups, thiols, silane groups, or combinations thereof. However, this is not essential, and instead, the silicon compound and/or the organic amine may be deposited without a reaction with the surface.

Any features of any embodiment of the first aspect may be independently as correspondingly described for any embodiment of any of the other aspects of the present invention.

In a second aspect, the present invention relates to a substrate processing system for depositing a thin film comprising silicon, nitrogen, and carbon on each of a plurality of substrates. The system comprises a reaction chamber configured to receive a substrate carrier supporting the plurality of substrates. The system further comprises a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen.

The system further comprises a second gas injector configured for providing a vapor-phase nitrogen precursor comprising an organic amine to the reaction chamber. The system further comprises a heater configured for heating and maintaining a process temperature in the reaction chamber. The system further comprises a controller configured to control the substrate processing system so as to form the thin film on each of the plurality of substrates.

The substrate processing system in accordance with embodiments of the second aspect of the present invention may be used for performing a method in accordance with embodiments of the first aspect of the present invention.

In some embodiments, the system further comprises a third gas injector configured for providing a vapor-phase co-reactant to the reaction chamber.

In embodiments, the gas injectors may comprise an inlet or a nozzle for providing the gas into the reaction chamber. In some embodiments, the gas injectors may comprise a tube comprising holes through which gas may flow into the reaction chamber. In embodiments, the first, second, and optional third gas injector may be different gas injectors. In some embodiments, the first, second and optional third gas injector may be the same gas injector.

In embodiments, the controller may be configured to execute instructions stored in a non-transitory computer readable medium so as to form the thin film on each of the plurality of substrates. The controller may control the gas injectors. The controller may control the heaters.

The process temperature typically refers to the temperature maintained within the reaction chamber during the deposition process, which may influence the reaction kinetics and film properties. In embodiments, the process temperature is maintained at temperatures at or below 650° C., preferably at or below 600° C., more preferably at or below 500° C., even more preferably at or below 450° C., yet more preferably at or below 400° C., when the silicon precursor is provided in the reaction chamber. In embodiments, the process temperature is maintained at temperatures at or below 650° C., preferably at or below 600° C., more preferably at or below 500° C., even more preferably at or below 450° C., yet more preferably at or below 400° C., when the nitrogen precursor is provided in the reaction chamber. In embodiments, the process temperature is maintained at temperatures at or below 650° C., preferably at or below 600° C., more preferably at or below 500° C., even more preferably at or below 450° C., yet more preferably at or below 400° C., when the co-reactant is provided in the reaction chamber. In embodiments, the process temperature is maintained at temperatures at or below 650° C., preferably at or below 600° C., more preferably at or below 500° C., more preferably at or below 450° C., yet more preferably at or below 400° C., when the substrate is present in the reaction chamber, or during the complete time period in which the substrate is present in the reaction chamber.

The substrate carrier is typically a device or structure that holds and supports one or more, e.g., a plurality of, substrates within the reaction chamber during processing, allowing for uniform exposure to the precursors and consistent film deposition. Examples of specific embodiments include wafer boats, susceptor plates, or carriers designed to accommodate multiple semiconductor wafers or other substrates.

The system may comprise a first source for providing the vapor-phase silicon precursor. The first source may be in gas communication, via a first valve and the first gas injector, with the reaction chamber. The controller may be operably connected to the first valve, wherein the controller is configured and programmed to open the first valve to provide a flow of the silicon precursor into the reaction chamber and to close the first valve to cease the flow of the silicon precursor into the reaction chamber. The first source may comprise any source that may hold and provide the silicon precursor in vapor-phase to the reaction chamber, such as a precursor vessel or a compressed gas cylinder, in which the silicon precursor may be contained as a pressurized gas.

The system may comprise a second source for providing the vapor-phase nitrogen precursor. The second source may be in gas communication, via a second valve and the second gas injector, with the reaction chamber. The controller may be operably connected to the second valve, wherein the controller is configured and programmed to open the second valve to provide a flow of the nitrogen precursor into the reaction chamber and to close the second valve to cease the flow of the nitrogen precursor into the reaction chamber. The second source may comprise any source that may hold and provide the nitrogen precursor in vapor-phase to the reaction chamber, such as a precursor vessel or a compressed gas cylinder, in which the nitrogen precursor may be contained as a pressurized gas.

The system may comprise a third source for providing the vapor-phase co-reactant. The third source may be in gas communication, via a third valve and the third gas injector, with the reaction chamber. The controller may be operably connected to the third valve, wherein the controller is configured and programmed to open the third valve to provide a flow of the co-reactant into the reaction chamber and to close the third valve to cease the flow of the co-reactant into the reaction chamber. The third source may comprise any source that may hold and provide the co-reactant in vapor-phase to the reaction chamber, such as a precursor vessel or a compressed gas cylinder, in which the co-reactant may be contained as a pressurized gas, or a co-reactant generator, such as an ozone generator.

The controller operably connected to the first valve may be the same as the controller operably connected to the second valve and/or the third valve, but the invention is not limited thereto.

In embodiments, the system is a semiconductor processing apparatus. In embodiments, the reaction chamber comprises the substrate.

Each source may have an inlet fluidically coupled, via a valve, to a source of a carrier gas. The carrier gas may be an inert gas such as N₂, He or Ar. The carrier gas may sweep a vapor of the precursor or co-reactant from the source along with it into the reaction chamber. The controller may be operably connected to the valve, wherein the controller is configured for providing said carrier gas, by opening the valve, to the source when the precursor or co-reactant is to be provided from the source to the reaction chamber.

The system may comprise heaters, that may be operated by a controller, for keeping the vapor-phase precursors and the optional co-reactant at or above the volatilization temperature so as to prevent undesirable condensation in the valves, filters, conduits, and other components associated with delivering the vapor-phase precursor and the optional co-reactant into the reaction chamber. A heater may be provided for heating the source, e.g., precursor vessel, and additional heaters may be provided for heating the various valves and gas flow lines between the sources and the reaction chamber, to prevent condensation and deposition of the precursors and the optional co-reactant on such components. Gas-conveying components between the sources and the reaction chamber may be provided in which the temperature is maintained above the volatilization temperature of the precursors and the optional co-reactant (i.e., “hot zone”).

In embodiments, the system further comprises a device for purging the reaction chamber, such as a device for performing inert gas purging on the reaction chamber or a device for vacuum pumping the reaction chamber. The system may further comprise a controller for activating said purging device to purge the reaction chamber. The controller may be configured and programmed to purge the reaction chamber between steps of providing the nitrogen precursor, providing the silicon precursor, and optionally providing the optional co-reactant. The controller may be configured and programmed to purge the reaction chamber after closing of a valve and before opening of another valve. The controller may be configured and programmed to purge the reaction chamber after closing of the first valve and before opening of the second valve, and/or after closing of the second valve and before opening of the first valve.

Any features of any embodiment of the second aspect may be independently as correspondingly described for any embodiment of any of the other aspects of the present invention.

In a third aspect, the present invention relates to a substrate processing system for depositing a thin film comprising a silicon, nitrogen, and carbon on a substrate. The system comprises a reaction chamber for receiving the substrate. The system further comprises a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen.

The system further comprises a second gas injector configured for providing a vapor-phase nitrogen precursor comprising an organic amine to the reaction chamber. The system further comprises a controller configured to control the substrate processing system so as to form said thin film on said substrate.

The substrate processing system in accordance with embodiments of the third aspect of the present invention may be used for performing a method in accordance with embodiments of the first aspect of the present invention.

Any features of any embodiment of the third aspect may be independently as correspondingly described for any embodiment of any of the other aspects of the present invention.

In a fourth aspect, the present invention relates to a thin film comprising silicon, nitrogen, and carbon. The film has a wet etch rate ratio of at most 0.5, preferably at most 0.2, more preferably at most 0.1.

The thin film in accordance with embodiments of the fourth aspect may be formable with a method in accordance with embodiments of the first aspect of the present invention.

Lower etch rate ratios typically indicate a higher etch selectivity. The wet etch rate ratio may be a ratio of a rate of wet etching the thin film over a rate of wet etching a thermal oxide material. The thermal oxide material, typically thermal silicon dioxide, is thus used as a reference. Said wet etch rate is typically that determined for an etch using 1:100 diluted hydrofluoric acid, for 1 minute, at room temperature (25° C.).

In embodiments, the thin film is a crystalline material. In embodiments, the thin film may be a silicon carbonitride. In embodiments, the thin film may be a carbon-doped silicon nitride. In embodiments, the thin film may be a material in which carbon atoms are incorporated into a silicon nitride lattice, resulting in a material comprising silicon, nitrogen, and carbon atoms. In embodiments, the carbon atoms may take the place of nitrogen atoms in said lattice, or may be located in inter-lattice spaces. In other words, the carbon atoms may be provided as substitutional atoms or interstitial atoms. In some embodiments, the nitrogen content is low, and the thin film may contain, e.g., a silicon lattice with nitrogen and carbon present as substitutional and/or interstitial dopants. In some embodiments, the thin film is an amorphous material.

In embodiments, the atomic ratio of an amount of nitrogen atoms over an amount of silicon atoms may be approximately 4/3, but this is not strictly required.

In embodiments, the thin film may consist of:
from 15 to 43 at-% silicon,
from 20 to 57 at-% nitrogen,
from 0.1 to 50 at-% carbon,
and at most 30 at-% of elements different than silicon, nitrogen, and carbon,
wherein the amounts in at-% add up to 100 at-%.

In embodiments, the thin film may consist of:
from 17 to 43 at-% silicon,
from 23 to 57 at-% nitrogen,
from 1 to 50 at-% carbon,
and at most 20 at-% of elements different than silicon, nitrogen, and carbon,
wherein the amounts in at-% add up to 100 at-%.

In embodiments, the thin film may consist of:
from 19 to 39 at-% silicon,
from 26 to 51 at-% nitrogen,
from 10 to 50 at-% carbon,
and at most 10 at-% of elements different than silicon, nitrogen, and carbon,
wherein the amounts in at-% add up to 100 at-%.

In some embodiments, the thin film may further contain oxygen, e.g., may be oxygen-doped. In embodiments, the thin film may be a silicon oxycarbonitride. In embodiments, the thin film may be a carbon-and oxygen-doped silicon nitride. In some embodiments, the thin film, further comprising oxygen, is a crystalline material. In embodiments, the thin film may be a silicon nitride material in which oxygen and/or carbon atoms are incorporated into a silicon nitride lattice, resulting in a material comprising silicon, nitrogen, oxygen, and carbon atoms. In embodiments, the oxygen and/or carbon atoms may take the place of nitrogen atoms in said lattice, or may be located in inter-lattice spaces. In other words, the oxygen and/or carbon atoms may be provided as substitutional atoms or interstitial atoms. In some embodiments, the nitrogen content is low, and the thin film may contain, e.g., a silicon lattice with nitrogen, carbon and oxygen present as substitutional and/or interstitial dopants. In some embodiments, the thin film, further comprising oxygen, is an amorphous material.

In embodiments, the thin film may consist of:
from 15 to 43 at-% silicon,
from 0.1 to 57 at-% nitrogen,
from 0.1 to 50 at-% carbon,
from 0.1 to 70 at-% oxygen,
and at most 30 at-% of elements different than silicon, nitrogen, carbon, and oxygen,
wherein the amounts in at-% for nitrogen and oxygen add up to at least 20 at-%, and
wherein the amounts in at-% (that is, of said silicon, said nitrogen, said carbon, said oxygen, and said different elements) add up to 100 at-%.

In embodiments, the thin film may consist of:
from 17 to 43 at-% silicon,
from 0.1 to 57 at-% nitrogen,
from 0.1 to 50 at-% carbon,
from 1 to 65 at-% oxygen,
and at most 20 at-% of elements different than silicon, nitrogen, carbon, and oxygen,
wherein the amounts in at-% for nitrogen and oxygen add up to at least 23 at-%, and
wherein the amounts in at-% (that is, of said silicon, said nitrogen, said carbon, said oxygen, and said different elements) add up to 100 at-%.

In embodiments, the thin film may consist of:
from 19 to 39 at-% silicon,
from 0.1 to 51 at-% nitrogen,
from 0.1 to 50 at-% carbon,
from 10 to 60 at-% oxygen,
and at most 10 at-% of elements different than silicon, nitrogen, carbon, and oxygen,
wherein the amounts in at-% for nitrogen and oxygen add up to at least 26 at-%, and
wherein the amounts in at-% (that is, of said silicon, said nitrogen, said carbon, said oxygen, and said different elements) add up to 100 at-%.

In embodiments, the thin film may contain from 0.1 to 50 at-% carbon, preferably from 1 to 50 at-% carbon, more preferably from 10 to 50 at-% carbon, even more preferably from 20 to 50 at-% carbon. In embodiments, the thin film may contain from 0.1 to 50 at-% carbon, preferably from 1 to 45 at-% carbon, more preferably from 10 to 40 at-% carbon, even more preferably from 20 to 30 at-% carbon. In preferred embodiments, the amount of carbon doping is adapted for providing said wet etch rate ratio, e.g., of at most 0.5, at most 0.2, or at most 0.1. It is an advantage of embodiments of the present invention that carbon doping alone may provide the thin film with improved etch selectivity. The presence of carbon, e.g., carbon doping, may effectively increase the wet etch rate ratio of the thin film, particularly when the concentration of the carbon doping is high.

In embodiments, the thin film may contain from 0.1 to 70 at-% oxygen, preferably from 1 to 65 at-% oxygen, more preferably from 5 to 60 at-% oxygen, even more preferably from 10 to 60 at-% oxygen.

In embodiments, the thin film may contain at most 30 at-%, preferably at most 20 at-%, more preferably at most 15 at-%, even more preferably at most 10 at-%, still more preferably at most 5 at-%, yet more preferably at most 2 at-%, most preferably 0 at-%, of elements different than silicon, nitrogen, carbon, and optional oxygen. In embodiments, the thin film may contain at most 10 at-%, preferably at most 5 at-%, more preferably at most 2 at-%, even more preferably at most 1 at-%, still more preferably at most 0.5 at-%, most preferably 0 at-%, of boron. In the state of the art, said carbon is sometimes provided by alkylborane, which however results in the introduction of boron impurities in the film. Limiting boron incorporation may avoid degradation of the film properties.

Any features of any embodiment of the fourth aspect may be independently as correspondingly described for any embodiment of any of the other aspects of the present invention.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

A description of an exemplary substrate processing system in accordance with embodiments of the present invention will now be provided, followed by an exemplary in accordance with embodiments of the present invention that may be performed therein.

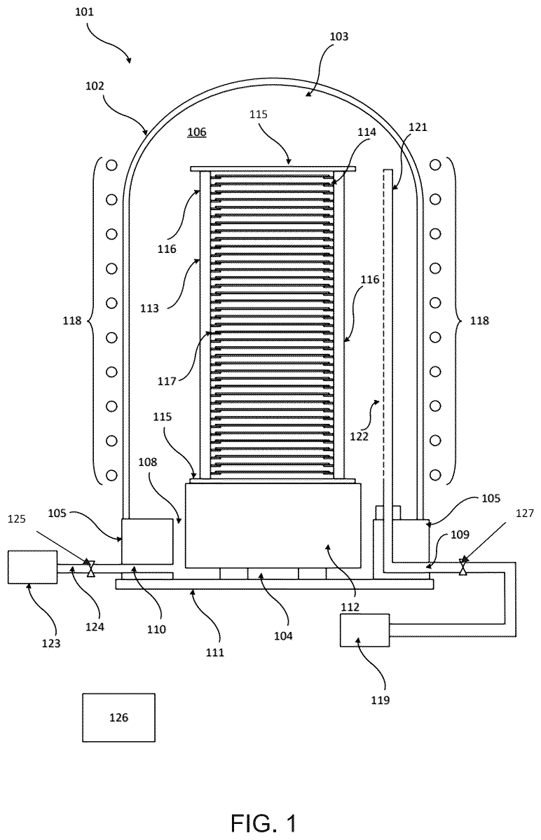

Referring to FIG. 1, a substrate processing system 101, which is in this example a semiconductor processing apparatus 101, according to embodiments of the present invention is shown. The semiconductor processing apparatus 101 comprises a reaction chamber 102 which is generally bell jar shaped, having a closed top end 103, a closable bottom end 104, and an interior space 106. The semiconductor processing apparatus 101 may be a vertical furnace. The reaction chamber 102 may accordingly extend in a vertical direction between the top end 103 and the bottom end 104. The semiconductor processing apparatus 101 may comprise a flange 105 for at least partially supporting the reaction chamber 102 at the bottom end 104. The flange 105 may be generally circular in shape as viewed along the vertical direction. The flange 105 may comprise a central opening 108 and one or more gas inlets 109 for providing the precursors and optional co-reactants into the interior space 106 of the reaction chamber 102. The flange may comprise one or more gas outlets 110 for removing gas from the interior space 106, e.g., for purging any unreacted vapor-phase precursors and optional co-reactants, and/or any vapor-phase reaction products from the interior space 106 of the reaction chamber 102. The flange 105 may be configured to partially close off the bottom end 104 of the reaction chamber 102.

In the present example, the semiconductor processing apparatus 101 comprises a doorplate 111 configured to at least partially close off the bottom end 104 of the reaction chamber 102. The doorplate 111 may support a pedestal 112 thereon. The pedestal 112 may be configured to support a substrate carrier 113, also referred to as a boat. In some embodiments, no pedestal may be provided and the substrate carrier 113 may be supported directly on the doorplate 111. The pedestal 112 (if included) and boat may be inserted into and removed from the reaction chamber 102 through the bottom end 104 by moving the doorplate 111 in a vertical direction.

The substrate carrier 113 is configured to support a plurality of substrates 114 therein. The plurality of substrates 114 may be spaced apart in a vertical direction. The substrate carrier 113 may comprise two end plates 115 spaced apart by a plurality of support rods 116. The plurality of support rods 116 may comprise a plurality of sets of slots 117 or projections for supporting the plurality of substrates, each set of slots 117 or projections being spaced apart from the other sets of slots 117 or projections in the vertical direction. Each set of slots 117 or projections being at a same vertical position forms a respective substrate receiving position. Embodiments of the present invention allow for forming a thin film containing silicon, nitrogen, and carbon, and optionally oxygen, on each of the plurality of substrates simultaneously.

The semiconductor processing apparatus 101 may comprise a heater for heating the reaction chamber 102 and thereby heating the interior space, for example in the form of heating coils 118 disposed around an outer surface of the reaction chamber 102.

The semiconductor processing apparatus 101 comprises at least one gas inlet 109 in the flange 105 for providing a gas or gases to the interior space 106 of the reaction chamber 102. The at least one gas inlet 109 may each be connected to one or more respective gas sources 119. The gas sources 119 may include process gas sources and purge gas sources. In particular, the gas sources 119 may comprise a gas source 119 for the nitrogen precursor, a gas source 119 for the silicon precursor, and optionally a gas source 119 for an optional co-reactant, e.g., an oxygen precursor. The gas sources 119 may be connected to the same gas inlet 109 or to different gas inlets 109. The gas inlets 109 may be categorized according to the type of gas to be provided therethrough; for example, the flange 105 may comprise one or more process gas inlets and one or more purge gas inlets.

The exemplary semiconductor processing apparatus 101 comprises at least one injector 121, each in fluid communication with a respective gas inlet 109. The semiconductor processing apparatus 101 may comprise the same number of injectors 121 as gas inlets 109, or may comprise fewer injectors 121 than gas inlets 109, that is, one or more gas inlets 109 may not be connected to an injector 121. In the present example, the injector 121 or each of the injectors 121 may extend in a vertical direction within the reaction chamber 102. In the present example, the injector 121 or each of the injectors 121 may comprise a series of holes 122 through which gas may flow into the reaction chamber 102, the holes 122 being spaced apart in a vertical direction.

The semiconductor processing apparatus 101 comprises at least one gas outlet 110 in the flange 105 for removing a gas or gases from the interior space 106 of the reaction chamber 102. The at least one gas outlet 110 may be in fluid communication with a vacuum pump 123 via an exhaust gas line 124, which may be used for purging of the reaction chamber 102.

The semiconductor processing apparatus 101 may comprise a controller 126 which may be configured to control various elements of the semiconductor processing apparatus 101. The controller 126 may comprise a memory for storing, for example, program instructions, setpoint values, characterisation data, and other data. The controller 126 may comprise a processor for executing program instructions which may be loaded from the memory. The controller 126 may be configured to receive data from sensors in the semiconductor processing apparatus 101, for example pressure sensors, temperature sensors, and/or other types of sensors. The controller 126 may be configured to control elements of the semiconductor processing apparatus 101 by sending control signals to, for example, gas flow control valves, heating elements, and/or water cooling elements.

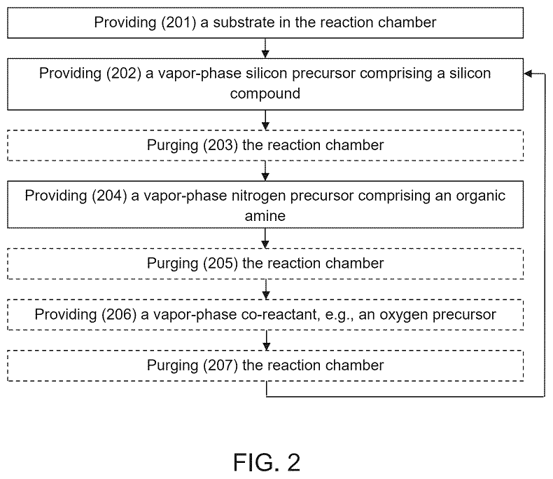

Simultaneous reference is made to FIG. 2, which is a block diagram with exemplary steps that may be performed in a method in accordance with embodiments of the present invention, for example, in a substrate processing system of the present invention, such as in a semiconductor processing apparatus 101 of the above example. In FIG. 2, boxes defined by dashed lines may be optional steps.

In a first step 201, a substrate 114 may be provided into the reaction chamber 102. More in particular, in the present example, a plurality of substrates 114 may be provided in the substrate carrier 113, which is introduced or positioned into the interior space 106 of the reaction chamber 102.

In subsequent steps, precursors and optional co-reactants may be provided from sources 119, through the inlet 109 and the injector 121, into the interior space 106 of the reaction chamber 102. Each precursor and optional co-reactant may be provided from a different source 119, through a different inlet 109 and injector 121, into said interior space.

In particular, after providing 201 the substrates 114 into the reaction chamber 102, a vapor-phase silicon precursor comprising a silicon compound may be provided 202 into the reaction chamber 102. In particular, the controller 126 may open a valve 127 connecting a source 119 containing the silicon precursor to the reaction chamber 102, for providing the silicon precursor into the reaction chamber 102. Thereby, a thin film comprising silicon may be formed on each of the substrates 114. If the silicon precursor contains carbon, the thus formed thin film may comprise carbon as well. After formation of the film, the valve 127 may be closed again by the controller 126.

Subsequently, the reaction chamber 102 may be purged 203, as described above, for removing any unreacted silicon precursor remaining in the reaction chamber 102.

Subsequently, a vapor-phase nitrogen precursor comprising an organic amine may be provided 204 into the reaction chamber 102. In particular, the controller 126 may open a valve 127 connecting a source 119 containing the nitrogen precursor to the reaction chamber 102, for providing the nitrogen precursor into the reaction chamber 102. Thereby, nitrogen is deposited on each of the substrates 114, so that the film now also contains nitrogen. As the nitrogen precursor contains the organic amine that contains carbon, carbon is typically also deposited in this step. After said deposition of nitrogen and carbon, the valve 127 connecting the source 119 containing the nitrogen precursor to the reaction chamber 102 may be closed again by the controller 126.

Subsequently, the reaction chamber 102 may again be purged 205, as described above, for removing any unreacted nitrogen precursor remaining in the reaction chamber 102.

Subsequently, a vapor-phase co-reactant, which may contain for example an oxygen precursor, may be provided 206 into the reaction chamber 102. In particular, the controller 126 may open a valve 127 connecting a source 119 containing the co-reactant to the reaction chamber 102, for providing the co-reactant into the reaction chamber 102. The co-reactant may then react with the thin films on the substrates 114. When the co-reactant is an oxygen precursor, oxygen is deposited on each of the substrates 114, so that the film now also contains oxygen. After said reaction of the co-reactant with the thin films, the valve 127 connecting the source 119 containing the co-reactant to the reaction chamber 102 may be closed again by the controller 126.

Subsequently, the reaction chamber may be purged 207. The controller 126 may open the valve 125 connecting the vacuum pump 123 to the reaction chamber 102, thereby removing any unreacted precursor, unreacted co-reactant, reaction products or contaminants from the interior space 106 through the gas outlet 110. After said removal, the valve 125 may be closed again by the controller 126.

Steps 202-207 may be performed cyclically, so that after said step of purging 207 the reaction chamber, the cycle is performed again, starting with providing a vapor-phase silicon precursor comprising a silicon compound 202 into the reaction chamber 102 again.

Although FIG. 2 shows a particular order of steps, the steps of providing 202 the silicon precursor, providing 204 the nitrogen precursor, and providing 206 the co-reactant may be performed in a different order. Furthermore, additional steps of providing 202 the silicon precursor, providing 204 the nitrogen precursor, or providing 206 the co-reactant may be added to the block diagram, for example, for increasing a concentration of an element provided by the added step into the film. In some cycles, providing 202 the silicon precursor, providing 204 the nitrogen precursor, or providing 206 the co-reactant may be omitted, for example, for reducing a concentration of an element provided by the omitted step in the film. Purging steps 203, 205, 207, performed in between providing different precursors and co-reactants, are optional, but may increase the film purity and the properties of the formed thin film.

While performing the above steps, the controller 126 may control the heater, such as the heating coils 118, for retaining the reaction chamber 102 at a process temperature that is preferably at most 650° C., more preferably at most 600° C., even more preferably at most 500° C., yet more preferably at most 450° C., still more preferably at most 400° C.

It is to be understood that although preferred embodiments, specific constructions and configurations, as well as materials, have been discussed herein for devices according to the present invention, various changes or modifications in form and detail may be made without departing from the scope of this invention. Functionality may be added or deleted from the block diagrams and operations may be interchanged among functional blocks. Steps may be added or deleted to methods described within the scope of the present invention.

1. A method for depositing a thin film comprising silicon, nitrogen, and carbon on a substrate, the method comprising:
providing the substrate in a reaction chamber, and then providing into the reaction chamber:
a vapor-phase silicon precursor comprising a silicon compound, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein at least one R is halogen, and
wherein each halogen, if present, is independently selected from a group consisting of F, Cl, Br, and I, and
a vapor-phase nitrogen precursor comprising an organic amine,
thereby forming the thin film on a portion of a surface of the substrate.

2. The method of claim 1, each of the optionally substituted C1 to C8 groups is independently selected from:
optionally substituted linear or branched C1 to C6 alkyls, and
optionally substituted aryls.

3. The method of claim 1, wherein each optional substituent is, if present, independently selected from a group consisting of F, Cl, Br, and I.

4. The method of claim 1, wherein at least one R of the silicon compound is an optionally substituted C1 to C8 group.

5. The method of claim 1, wherein the method is an atomic layer deposition process comprising pulsing, cyclically, into said reaction chamber:
said silicon precursor, and then
said nitrogen precursor.

6. The method of claim 1, wherein the organic amine has the chemical formula NR¹³R¹⁴R¹⁵, wherein:
R¹³ is an optionally substituted C1 to C8 group, and wherein each of R¹⁴ and R¹⁵ is independently selected from H and optionally substituted C1 to C8 groups, or R¹³ and R¹⁴ together with N form an optionally substituted four to ten membered carbon-containing ring, and wherein:
R¹⁴ and R¹⁵ together with N form an optionally substituted four to ten membered carbon-containing ring, or
R¹⁵ is selected from H and optionally substituted C1 to C8 groups.

7. The method of claim 6, wherein R¹³ is an optionally substituted C1 to C4 group, and wherein each of R¹⁴ and R¹⁵ is H.

8. The method of claim 7, wherein the organic amine is an alkylamine, preferably methylamine.

9. The method of claim 1, wherein the organic amine has the chemical formula R¹⁶R¹⁷N—(CR¹⁸R¹⁹)_{y}—NR²⁰R²¹, with y an integer in the range from 1 to 4, wherein:
each of R¹⁶ and R¹⁷ is independently selected from H and optionally substituted C1 to C8 groups, or R¹⁶ and R¹⁷ together with the N to which they are bonded form an optionally substituted four to ten membered ring,
each of R²⁰ and R²¹ is independently selected from H and optionally substituted C1 to C8 groups, or R²⁰ and R²¹ together with the N to which they are bonded form an optionally substituted four to ten membered ring, and
each R¹⁸ and R¹⁹ is independently selected from H and optionally substituted C1 to C8 groups.

10. The method of claim 9, wherein each of R¹⁶ R¹⁷, R²⁰, R²⁰, and R²¹ is H.

11. The method of claim 1, wherein the silicon compound is a silicon halide, preferably a silicon chloride.

12. The method of claim 11, wherein the silicon compound is tetrachloromonosilane, hexachlorodisilane, or octachlorotrisilane, preferably hexachlorodisilane or octachlorotrisilane.

13. The method of claim 1, wherein the step of providing said silicon precursor and said nitrogen precursor is performed at a temperature of at most 650° C.

14. The method of claim 1, comprising a step of providing an oxygen precursor into the reaction chamber, wherein the formed thin film further comprises oxygen.

15. A substrate processing system for depositing a thin film comprising silicon, nitrogen, and carbon on each of a plurality of substrates, the system comprising:
a reaction chamber configured to receive a substrate carrier supporting the plurality of substrates,
a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen, and
a second gas injector configured for providing a vapor-phase nitrogen precursor comprising an organic amine to the reaction chamber,
a heater configured for heating and maintaining a process temperature in the reaction chamber, and
a controller configured to control the substrate processing system so as to form the thin film on each of the plurality of substrates.

16. A substrate processing system for depositing a thin film comprising a silicon, nitrogen, and carbon on a substrate, the system comprising:
a reaction chamber for receiving the substrate,
a first gas injector configured for providing a vapor-phase silicon precursor comprising a silicon compound to the reaction chamber, wherein the silicon compound is selected from a group consisting of SiR¹R²R³R⁴ and R⁵R⁶R⁷Si—(XR⁸R⁹)ₘ—SiR¹⁰R¹¹R¹²,
wherein m is an integer in the range from 0 to 4,
wherein each X is independently selected from a group consisting of Si and C,
wherein each R is independently selected from a group consisting of halogen, H, and optionally substituted C1 to C8 groups,
wherein each halogen, if present, is independently selected from a group consisting of F, Cl, Br, and I, and
wherein at least one R is halogen, and
a second gas injector configured for providing a vapor-phase nitrogen precursor comprising an organic amine to the reaction chamber, and
a controller configured to control the substrate processing system so as to form said thin film on said substrate.

17. A thin film comprising silicon, nitrogen, and carbon having a wet etch rate ratio of at most 0.5.

18. The thin film of claim 17, wherein the thin film contains from 0.1 to 50 at-% carbon.

19. The thin film of claim 17, containing at most 10 at-% boron.
